(19) United States
(12) Patent Application Publication
(10) Pub. No.: US 2025/0324579 A1
(43) Pub. Date: Oct. 16, 2025

(54) SEMICONDUCTOR DEVICE AND FABRICATION METHOD THEREOF

(71) Applicant: Yangtze Memory Technologies Co., Ltd., Wuhan (CN)

(72) Inventors: Di WANG, Wuhan (CN); Wenxi ZHOU, Wuhan (CN); Zhiliang XIA, Wuhan (CN)

(21) Appl. No.: 18/897,546

(22) Filed: Sep. 26, 2024

(30) Foreign Application Priority Data
Apr. 16, 2024 (CN) 202410462962.2

(51) Int. Cl. H10B 12/00

(52) U.S. Cl. CPC H10B 12/50; H10B 12/03; H10B 12/315; H10B 12/482

(57) ABSTRACT

Examples of the present disclosure disclose a semiconductor device and a fabrication method thereof. The semiconductor device includes a first semiconductor structure. The first semiconductor structure includes a transistor including a semiconductor layer extending at least in a first direction and a gate layer extending in a second direction. The semiconductor layer has a first end and a second end disposed oppositely in the first direction with an intermediate region therebetween. The semiconductor layer includes a first semiconductor layer and a second semiconductor layer disposed adjacently in the third direction. The gate layer includes a first gate layer and a second gate layer disposed adjacently in the third direction. The first gate layer and the second gate layer are located between the first semiconductor layer and the second semiconductor layer.

### CROSS-REFERENCE TO RELATED APPLICATIONS

This application claims priority to Chinese Patent Application No. 202410462962.2, filed on Apr. 16, 2024, which is hereby incorporated by reference in its entirety.

### TECHNICAL FIELD

The examples of the present disclosure relate to the field of semiconductor technology, and particularly to a semiconductor device and a fabrication method thereof.

### BACKGROUND

Some semiconductor devices, such as dynamic random access memories (DRAMs), may include a memory array and a peripheral circuit that may control the memory array, and operate the memory array to perform read, write or refresh operations. In order to improve the performance of memory devices, there are many spaces for improvements for memory devices and fabrication method thereof.

### SUMMARY

According to some aspects of examples of the present disclosure, there is provided a semiconductor device including a first semiconductor structure. The first semiconductor structure includes a transistor including a semiconductor layer extending at least in a first direction and a gate layer extending in a second direction; the semiconductor layer having a first end and a second end disposed oppositely in the first direction with an intermediate region therebetween; the semiconductor layer comprising a first semiconductor layer and a second semiconductor layer disposed adjacently in a third direction, and the gate layer comprising a first gate layer and a second gate layer disposed adjacently in the third direction; the first gate layer, the second gate layer being located between the first semiconductor layer and the second semiconductor layer; the third direction intersecting the second direction, and a plane constituted by the third direction and the second direction intersecting the first direction; wherein the first end of the first semiconductor layer has a first distance from the first end of the second semiconductor layer in the third direction, the intermediate region of the first semiconductor layer has a second distance from the intermediate region of the second semiconductor layer in the third direction; and the first distance is greater than the second distance.

In some examples, the first semiconductor structure further comprises: a wall structure extending in the second direction; the semiconductor layer being located on two sides of the wall structure disposed oppositely in the third direction.

In some examples, the first semiconductor structure further comprises: a first dielectric layer located between the wall structure and the semiconductor layer; the wall structure comprising a second dielectric layer, a conductive layer and a third dielectric layer stacked in the first direction, the second dielectric layer being located on a side of the conductive layer close to the first end in the first direction; wherein a size of the second dielectric layer in the third direction is smaller than a size of the conductive layer in the third direction.

In some examples, the second end of the first semiconductor layer has a third distance from the second end of the second semiconductor layer in the third direction, and the third distance is greater than the second distance.

In some examples, a size of the third dielectric layer in the third direction is smaller than a size of the conductive layer in the third direction.

In some examples, the semiconductor layer surrounds two sides of the wall structure disposed oppositely in the third direction and surrounds one side of the wall structure in the first direction; the semiconductor layer comprises two first ends exposing another side of the wall structure in the first direction; and the semiconductor layer provides channels for two transistors adjacent in the third direction.

In some examples, the first end comprises a protrusion extending in a direction away from the wall structure.

In some examples, the constituting material for the semiconductor layer comprises indium gallium zinc oxide IGZO.

In some examples, the first semiconductor structure further comprises: a gate dielectric layer located between the semiconductor layer and the gate layer.

In some examples, the first semiconductor structure further comprises: a capacitive structure located on a side of the semiconductor layer close to the first end and coupled with the first end.

In some examples, the capacitive structure comprises: a first electrode, a fourth dielectric layer and a second electrode, the fourth dielectric layer being located between the first electrode and the second electrode; wherein the first electrode is coupled with the first end; and a plurality of the capacitive structures are coupled via the second electrodes.

In some examples, the first electrode extends in the first direction and comprises air gap.

In some examples, the first semiconductor structure further comprises: a bit line located on a side of the semiconductor layer close to the second end and coupled with the second end.

In some examples, the semiconductor device further comprises a second semiconductor structure located on a side of the bit line away from the semiconductor layer; the second semiconductor structure comprises a peripheral circuit, and the second semiconductor structure is bonded with the first semiconductor structure.

According to some aspects of examples of the present disclosure, there is provided a semiconductor device comprising: a semiconductor layer extending at least in a first direction; the semiconductor layer having a first end and a second end disposed oppositely in the first direction; a wall structure extending in a second direction; the semiconductor layer being located on two sides of the wall structure disposed oppositely in a third direction; the third direction intersecting the second direction, and a plane constituted by the third direction and the second direction intersecting the first direction; a first dielectric layer located between the wall structure and the semiconductor layer; wherein the wall structure comprises a second dielectric layer, a conductive layer and a third dielectric layer stacked in the first direction, the second dielectric layer being located on a side of the conductive layer close to the first end in the first direction; a size of the second dielectric layer in the third direction is smaller than a size of the conductive layer in the third direction.

In some examples, a size of the third dielectric layer in the third direction is smaller than a size of the conductive layer in the third direction.

In some examples, the semiconductor layer surrounds the two sides of the wall structure disposed oppositely in the third direction and surrounds one side of the wall structure in the first direction; the semiconductor layer comprises two first ends exposing another side of the wall structure in the first direction.

In some examples, the first end comprises a protrusion extending in a direction away from the wall structure.

In some examples, the semiconductor layer comprises a first semiconductor layer and a second semiconductor layer disposed adjacently in the third direction, the semiconductor device further comprises: a gate layer extending in the second direction and located on two sides of the wall structure disposed oppositely in the third direction; the gate layer comprising a first gate layer and a second gate layer disposed adjacently in the third direction; the first gate layer, the second gate layer being located between the first semiconductor layer and the second semiconductor layer; and a gate dielectric layer located between the semiconductor layer and the gate layer.

In some examples, the semiconductor device further comprises: a capacitive structure located on a side of the semiconductor layer close to the first end and coupled with the first end.

In some examples, the capacitive structure comprises: a first electrode, a fourth dielectric layer and a second electrode, the fourth dielectric layer being located between the first electrode and the second electrode; wherein the first electrode is coupled with the first end; and a plurality of the capacitive structures are coupled via the second electrodes.

In some examples, the first electrode extends in the first direction and comprises air gap.

In some examples, the semiconductor device further comprises: a bit line located on a side of the semiconductor layer close to the second end and coupled with the second end.

In some examples, the wall structure, the semiconductor layer and the bit line are located in a first semiconductor structure; and the semiconductor device further comprises: a second semiconductor structure located on a side of the bit line away from the semiconductor layer; the second semiconductor structure comprising a peripheral circuit, and the second semiconductor structure being bonded with the first semiconductor structure.

According to some aspects of examples of the present disclosure, there is provided a fabrication method of a semiconductor device comprising forming a first semiconductor structure, the method of forming the first semiconductor structure comprising: forming a first dielectric material layer, a first conductive material layer and a second dielectric material layer stacked in the first direction; forming a first trench extending through the second dielectric material layer, the first conductive material layers and at least a part of thickness of the first dielectric material layer, the first trench extending in a second direction; removing a part of the first dielectric material layer on bottom of the first trench to form a first opening having an opening direction toward a third direction, thereby forming the wall structure; wherein a size of the remaining first dielectric material layer in the third direction is smaller than a size of the first conductive material layers in the third direction; the third direction intersects the second direction, and a plane constituted by the third direction and the second direction intersects the first direction; forming the first dielectric layer and the semiconductor layer on two sides of the wall structure in the third direction with the first dielectric layer between the wall structure and the semiconductor layer; wherein the semiconductor layer has a first end and a second end disposed oppositely in the third direction, a part of the first dielectric layer is located on the inner wall of the first opening, and a part of the first end is located on the inner wall of the first opening.

In some examples, the method of forming the wall structure further comprises: removing a part of the second dielectric material layer at an opening side of the first trench to form a second opening having an opening direction toward the third direction; wherein a size of the remaining second dielectric material layer in the third direction is smaller than a size of the first conductive material layers in the third direction; a part of the first dielectric layer is located on inner wall of the second opening and a part of the second end is located on inner wall of the second opening.

In some examples, the method of forming the semiconductor layer comprises: forming a first dielectric layer on two sides of the first trench in the third direction; forming a semiconductor material layer covering the first dielectric layer in the third direction and covering the bottom of the first trench in the first direction; penetrating through the semiconductor material layer on the bottom of the first trench in the first direction to form the semiconductor layer, with the first end being located on the bottom of the first trench.

In some examples, the semiconductor material layer further covers the remaining second dielectric material layer in the first direction.

In some examples, the method of forming the semiconductor layer further comprises: forming a protrusion by a remainder of the semiconductor material layer when penetrating through the semiconductor material layer; wherein the protrusion extends in a direction away from the wall structure.

In some examples, the method of forming the semiconductor layer further comprises: forming a second trench extending through the semiconductor material layer in the first direction, the second trench extending in the third direction.

In some examples, the method of forming the first semiconductor structure further comprises: forming a gate dielectric layer and a second conductive material layer covering the semiconductor layer at least in the third direction and covering the bottom of the first trench in the first direction; penetrating through at least the second conductive material layer in the first direction to form the gate layer.

In some examples, the method of forming the first semiconductor structure further comprises: forming a capacitive structure on a side of the semiconductor layer close to the first end, an electrode of the capacitive structure close to the first end being coupled with the first end.

In some examples, the method of forming the first semiconductor structure further comprises: forming a bit line on a side of the semiconductor layer close to the second end, the bit line being coupled with the second end.

In some examples, the fabrication method of the semiconductor device further comprises: bonding a second semiconductor structure on a side of the bit line away from the semiconductor layer, the second semiconductor structure comprising a peripheral circuit.

Examples of the present disclosure provide a semiconductor device comprising a first semiconductor structure comprising a transistor, the transistor comprising a semiconductor layer extending at least in a first direction and a gate layer extending in a second direction, the semiconductor layer having a first end and a second end disposed oppositely in the first direction with an intermediate region therebetween; the semiconductor layer comprising a first semiconductor layer and a second semiconductor layer disposed adjacently in the third direction, the first end of the first semiconductor layer having a first distance from the first end of the second semiconductor layer in the third direction, the intermediate region of the first semiconductor layer having a second distance from the intermediate region of the second semiconductor layer in the third direction; wherein the first distance is greater than the second distance, which may increase the distance between first ends of the two semiconductor layers, reduce the electrical interference between the first semiconductor layer and the second semiconductor layer, and facilitates enlarging the process window for fabricating the semiconductor layer while further reducing size and improving integration level.

### BRIEF DESCRIPTION OF DRAWINGS

FIG. 1 is a diagram of a memory array illustrated according to an example implementation;

FIG. 2 is a diagram of a semiconductor device illustrated according to an example implementation;

FIGS. 3 to 7 are diagrams of a semiconductor device illustrated according to an example of the present disclosure;

FIG. 8 is a flow diagram of a fabrication method of a semiconductor device illustrated according to an example of the present disclosure;

FIGS. 9 to 23 are diagrams of a fabrication method of a semiconductor device illustrated according to an example of the present disclosure; and

FIGS. 24 and 25 are diagrams of an example system illustrated according to an example of the present disclosure.

### DETAILED DESCRIPTION

Example implementations of the present disclosure will be described in greater detail below with reference to the accompanying drawings. Although example implementations of the present disclosure are shown in drawings, it is to be appreciated that the present disclosure may be implemented in various forms rather than being limited to the specific implementations as set forth herein. In contrast, these implementations are provided to understand the present disclosure more thoroughly and convey the scope of the present disclosure completely to those skilled in the art.

In the following description, a large amount of specific details are presented to provide thorough understanding of the present disclosure. However, it is obvious to one skilled in the art that the present disclosure may be implemented without one or more of these details. In other examples, in order to avoid confusion with the present disclosure, some technical features well known in the art are not described. That is, not all features of the practical examples are described herein, and well-known functions and structures are not described in detail.

It is to be appreciated that although terms such as first, second, third etc. may be used to describe elements, components, regions, layers and/or parts, these elements, components, regions, layers and/or parts should not be limited by these terms. These terms are only used to differentiate one element, component, region, layer or part from another element, component, region, layer or part. Therefore, without departing from the teaching of the present disclosure, the first element, component, region or part discussed below may represent the second element, component, region, layer or part. While discussing the second element, component, region, layer or part, it does not necessarily indicate the existence of the first element, component, region, layer or part in the present disclosure.

Spatial relationship terms such as “under”, “below”, “beneath”, “over”, “on” etc. may be used herein for convenient description to describe the relationship of one element or feature shown in the drawings relative to other elements or features. It is to be appreciated that spatial relationship terms are further intended to include different orientations of devices in use and operation in addition to orientations shown in the figures. For example, if the device in a figure is inverted, then an element or feature described as “under” or “below” or “beneath” another element or feature will be “on” the other element or feature. Accordingly, example terms “under” and “below” may include two orientations “on” and “under”. A device may be otherwise oriented (rotated by 90 degrees or other orientations) and spatial description terms used herein should be interpreted accordingly.

Terms are used herein only for describing specific examples rather than limiting the present disclosure. As used herein, the singular form “a”, “an” and “the” are also intended to include the plural form unless otherwise stated in the context. It is also understood that while used in the description, terms “consist” and/or “include” confirm the presence of said features, integers, steps, operations, elements and/or components, but do not exclude the presence or addition of one or more other features, integers, steps, operations, elements, components and/or combinations thereof. As used herein, the term “and/or” includes any and all combinations of relevant listed items.

It should be understood that “some examples” or “an example” as mentioned throughout the description means that particular features, structures, or characteristics related to the example are included in at least one example of the present disclosure. Therefore, “in some examples” or “in an example” occurring throughout the description does not necessarily refer to the same example. In addition, these particular features, structures, or characteristics may be incorporated in one or more examples in any suitable manners. It should be understood that size of the sequence numbers of the above-described processes do not mean the sequential order of executions in various examples of the present disclosure. The execution order of the processes should be determined by their functions and internal logics and should not limit the implementation of the examples of the present disclosure.

The semiconductor device in examples of the present disclosure may be a DRAM or at least a part of memory devices in a DRAM, which is suitable for use in a double-data-rate synchronous dynamic random access memory adopting DDR4 memory specification and DDR5 memory specification, and low-power consumption double-data-rate synchronous dynamic random access memory adopting LPDDR5 memory specification. It is to be noted that examples of the present disclosure are not limited to DRAM. However, in the followed description, only DRAM is illustrated as an example for clear description.

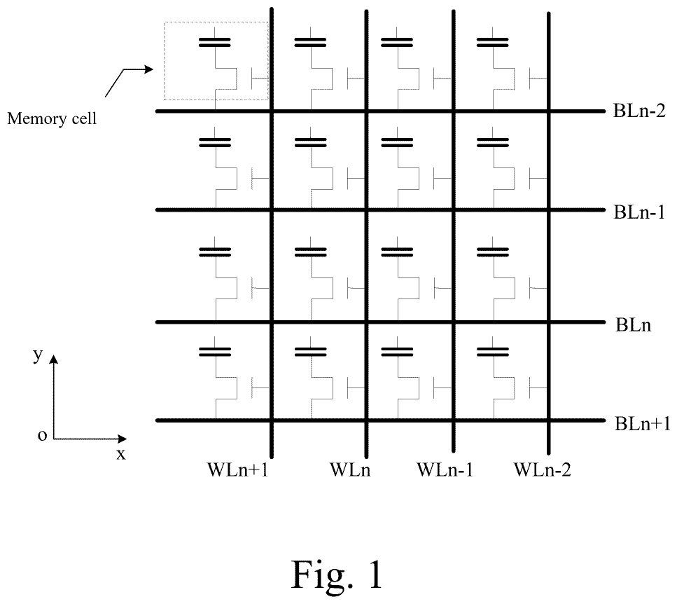

In a DRAM, a memory array may be arranged in rows and columns such that memory cells may be addressed by specifying their rows and columns in the array. A memory array includes a plurality of word lines and a plurality of bit lines intersecting each other. A memory cell on the intersection point of a selected word line and a selected bit line is selected to perform read, write or refresh operation. As illustrated in FIG. 1, the memory array may include a plurality of word lines WLn, WLn+1, WLn−1 and WLn−2, a plurality of bit lines BLn, BLn+1, BLn−1 and BLn−2, which intersect each other. The memory cells in the memory array may include capacitors and transistors. One memory cell may include one transistor and one capacitor. The word lines may also be a conductive structure such as the gate layer which serves a gate of transistor. One controlled terminal (source) of a transistor is coupled with one electrode of the capacitor, another controlled terminal (drain) of the transistor is coupled with a bit line. Another electrode of the capacitor may be grounded or applied with another voltage such as Vdd/2. As illustrated in FIG. 1, the memory cell array is arranged as an array of x rows and y columns. Rows and columns may be perpendicular or not perpendicular to each other. The x direction may be the third direction as mentioned in examples of the present disclosure, and the y direction may be the second direction as mentioned in examples of the present disclosure. The extension direction of a bit line may be parallel to or form an angle with x direction. The extension direction of a word line may be parallel to or form an angle with y direction. The orthographic projection of a word line on xoy plane is perpendicular to the orthographic projection of a bit line on the xoy plane, or not perpendicular, but forms an angle therebetween, which is not limited in examples of the present disclosure. The z direction illustrated in the following description may be the first direction, may be perpendicular to the xoy plane, or just intersect the xoy plane rather than being perpendicular thereto.

While performing a read or write operation, it is possible to select a respective word line with the word line selection signal, and select a respective bit line with the column selection signal. Simultaneously selecting a word line and a bit line may address the selected memory cell. Now, the transistor of the selected memory cell is turned on due to the operating voltage applied by the word line. Therefore, it is possible to perform read, write or refresh operation on the selected memory cell. In some examples, the capacitor may be substituted for other storage structures including, but not limited to phase change storage structure, resistance change storage structure or magnetism change storage structure.

In some examples, logic 1 and 0 are represented by the much and less of charges stored in the capacitor or the high and low of voltage difference across the capacitor. The voltage signals on the word line are applied to the gate to control the on or off of the transistor, thereby enabling the select or unselect of the capacitor, and in turn enabling the reading of data information stored in the capacitor via the bit line or enabling the writing of data into the capacitor for storage via the bit line.

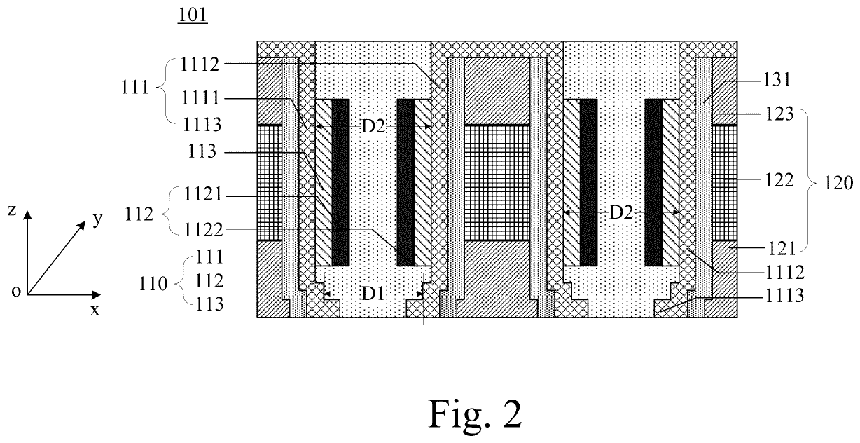

According to some aspects of examples of the present disclosure, FIG. 2 provides a semiconductor device including a first semiconductor structure. The first semiconductor structure 101 includes a transistor 110 including a semiconductor layer 111 extending in z direction and a gate layer 112 extending in y direction. The semiconductor layer 111 has a first end and a second end disposed oppositely in z direction with an intermediate region therebetween. The semiconductor layer 111 includes a first semiconductor layer 1111 and a second semiconductor layer 1112 disposed adjacently in x direction; and the gate layer 112 includes a first gate layer 1121 and a second gate layer 1122 disposed adjacently in x direction. The first gate layer 1121 and the second gate layer 1122 are located between the first semiconductor layer 1111 and the second semiconductor layer 1112. The x direction intersects the y direction, and a plane constituted by the x direction and the y direction intersects the z direction. The first end of the first semiconductor layer 1111 has a first distance from the first end of the second semiconductor layer 1112 in the x direction, which is denoted as D1. The intermediate region of the first semiconductor layer 1111 has a second distance from the intermediate region of the second semiconductor layer 1112 in the x direction, which is denoted as D2. The first distance is less than or equal to the second distance.

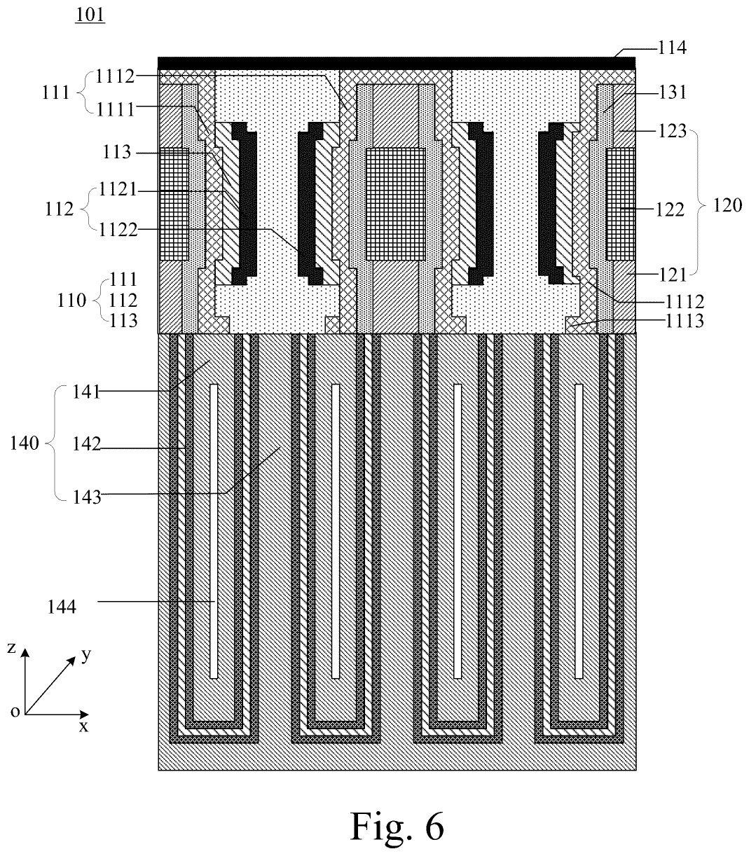

The transistor 110 may include the semiconductor layer 111 and a gate dielectric layer 113 and gate layer 112 on the semiconductor layer 111. The gate layer 112 serves as the control gate or word line of the transistor 110, and the semiconductor layer 111 serves as the channel of the transistor 110. the transistor 110 may be controlled to be turned on and off by applying a voltage through the gate layer 112. In an example, the transistor 110 is controlled to be turned on and off by controlling the corresponding semiconductor layer 111 to be turned on and off. At least a part of the semiconductor layer 111 may extend in the yoz plane. The two ends of the semiconductor layer 111 disposed oppositely in the z direction are denoted as the first end and the second end respectively. The region between the first end and the second end is the intermediate region. The first end and second end may have the same type of doping and may serve as active regions (drain or source, whose position may be exchangeable) of the transistor 110. The intermediate region between the first end and second end may be doped with a doping type opposite to the first end and serve as the channel of the transistor 110. The gate layer 112 covers the intermediate region between the first end and the second end in the x direction. The first end, second end and intermediate region in examples of the present disclosure are different region positions in the semiconductor layer 111 only for facilitating illustration of the scheme of the present example, and may have no distinct boundaries in practical physical structures. The first end may be the end in negative z direction in the drawing, may be the lower end of the semiconductor layer 111, may be configured to be coupled with the capacitive structure 140; and the second end may be the end in positive z direction in the drawing, may be the top end of the semiconductor layer 111 and may be configured to be coupled with the bit line 114 (as shown in FIG. 6 below).

In an example, the constituting material for the semiconductor layer 111 may include any semiconductor material known in the art, including, but not limited to: monoatomic semiconductor material such as silicon, germanium, III-V compound semiconductor material, II-VI compound semiconductor material, organic semiconductor material or other semiconductor material known in the art such as single crystalline silicon, poly-crystalline silicon, germanium, silicon carbide or indium gallium zinc oxide IGZO, etc. The constituting material for the gate layer 112 includes, but not limited to conductive materials such as tungsten, gold, silver, copper, chromium, nickel, titanium or aluminum, etc. The gate dielectric layer 113 includes, but not limited to insulating materials such as silicon oxide, silicon nitride, silicon oxynitride, silicon nitride or aluminum oxide, etc.

As shown in FIG. 2, the semiconductor layer 111 may be located on two sides of the wall structure 120 disposed oppositely in x direction. The wall structure 120 extends in the y direction. The semiconductor layer 111 and the gate layer 112 are located between two adjacent wall structures 120. The wall structures 120 provide an attachment surface for the semiconductor layer 111. The first semiconductor layer 1111 may be located on the right side of the wall structure 120 and the second semiconductor layer 1112 may be located on the left side of the wall structure 120. The first gate layer 1121 may be located on the right side of the wall structure 120 and the second gate layer 1122 may be located on the left side of the wall structure 120. The second end of the first semiconductor layer 1111 and the second end of the second semiconductor layer 1112 may be a continuous structure, and one semiconductor layer 111 may cover one side of the wall structure 120 in the z direction and two surfaces of the wall structure 120 disposed oppositely in the x direction. One semiconductor layer 111 may include one first semiconductor layer 1111 and one second semiconductor layer 1112. Second ends of the first semiconductor layer 1111 and the second semiconductor layer 1112 are connected by the semiconductor layer 111 extending in the x direction. The first semiconductor layer 1111 and the second semiconductor layer 1112 correspond to two transistors 110 respectively. Alternatively, the cross-sectional shape of the semiconductor layer 111 in xoz plane may be U or inverted U shape including two first ends and one second end covering the top surface of wall structure 120 with the two first ends enclosing an opening exposing the wall structure 120. One semiconductor layer 111 corresponds to two transistors 110, with the first semiconductor layer 1111 and the second semiconductor layer 1112 extending in the z direction respectively. For example, the first transistor 110 may include a first semiconductor layer 1111 on the right side of one wall structure 120 and a first gate layer 1121 on the first semiconductor layer 1111, including a part of the first gate layer 1121 overlapping the first semiconductor layer 1111 in the x direction, and a gate dielectric layer 113 between the first semiconductor layer 1111 and the first gate layer 1121.

In some examples, film layer of the U-shaped semiconductor layer 111 shown in FIG. 2 that covers the wall structure 120 in the z direction is broken or removed such that the second end of the first semiconductor layer 1111 and the second end of the second semiconductor layer 1112 are not connected by the semiconductor layer 111. The part of the U-shaped semiconductor layer 111 that covers the wall structure 120 in the z direction as shown in FIG. 2 provides a large area and smooth contacting surface for bit lines 114 to reduce the contact gaps between bit lines 114 and the semiconductor layer 111, improve the stability of devices, and omit the process step of removing the semiconductor layer 111 to expose the wall structure 120, thereby reducing the manufacturing costs.

While manufacturing the semiconductor device, based on the trench extending through the wall structure 120 and the semiconductor material layer covering the bottom and sidewalls of the trench, the semiconductor material layer may also cover the top surface of the wall structure 120; the semiconductor material layer on the bottom of trench is etched and penetrated to form the first semiconductor layer 1111 and the second semiconductor layer 1112 with the first end on the bottom of trench and being exposed; and the first distance D1 of the first end on the bottom of the trench in the x direction is less than or equal to the second distance D2 between the intermediate region of the first semiconductor layer 1111 and the intermediate region of the second semiconductor layer 1112 in the x direction. In some other examples, it is possible to etch the bottom of the trench to form an opening extending in the x direction such that the formed semiconductor material layer extends towards the wall structure 120 in the x direction, facilitating enlarging process windows for deposition and etching of the film layer, and the first distance D1 of the formed semiconductor material layer is greater than the second distance D2, thereby reducing the electrical interference between the first semiconductor layer 1111 and the second semiconductor layer 1112.

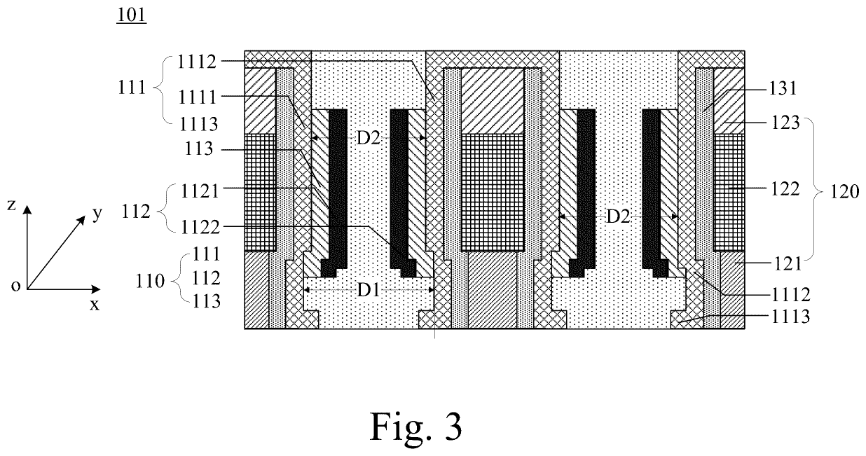

According to some aspects of examples of the present disclosure, FIG. 3 provides a semiconductor device including a first semiconductor structure 101. The first semiconductor structure 101 includes a transistor 110 including a semiconductor layer 111 at least extending in a first direction (z direction) and a gate layer 112 extending in a second direction (y direction). The semiconductor layer 111 has a first end and a second end disposed oppositely in the first direction (z direction) with an intermediate region therebetween. The semiconductor layer 111 includes a first semiconductor layer 1111 and a second semiconductor layer 1112 disposed adjacently in a third direction (x direction); and the gate layer 112 includes a first gate layer 1121 and a second gate layer 1122 disposed adjacently in the third direction. The first gate layer 1121 and the second gate layer 1122 are located between the first semiconductor layer 1111 and the second semiconductor layer 1112. The third direction intersects the second direction, and a plane constituted by the third direction and the second direction intersects the first direction. The first end of the first semiconductor layer 1111 has a first distance from the first end of the second semiconductor layer 1112 in the x direction. The intermediate region of the first semiconductor layer 1111 has a second distance from the intermediate region of the second semiconductor layer 1112 in the x direction. The first distance D1 is greater than the second distance D2.

Unlike the semiconductor layer 111 in FIG. 2, the first semiconductor layer 1111 in FIG. 3 has a part extending towards its wall structure 120, and the first distance D1 between the first end of the first semiconductor layer 1111 and the first end of the second semiconductor layer 1112 in the x direction is greater than the second distance D2 between the intermediate region of the first semiconductor layer 1111 and the intermediate region of the second semiconductor layer 1112 in the x direction, which facilitates increasing the spacing distance between the two first ends and reducing electrical interference between the first semiconductor layer 1111 and the second semiconductor layer 1112.

In some examples, with reference to FIG. 3, the first semiconductor structure 101 further includes a wall structure 120 extending in the y direction. The semiconductor layer 111 is located on two sides of the wall structure 120 disposed oppositely in the x direction and between two adjacent wall structures 120. The gate layer 112 is located between two adjacent wall structures 120. The wall structure 120 extending in the y direction provides an attachment plane for the semiconductor layer 111 and can provide support for the semiconductor layer 111. The semiconductor layer 111 covers, in the x direction, two sides of the wall structure 120 disposed oppositely in the x direction, and may cover, in the z direction, one surface of the wall structure 120 in the z direction. The semiconductor layer 111 has a U-shaped cross-section in xoz plane and the second end of the first semiconductor layer 1111 and the second end of the second semiconductor layer 1112 on the same wall structure 120 are connected. The semiconductor layer 111 may cover only two sides of the wall structure 120, and the second end of the first semiconductor layer 1111 and the second end of the second semiconductor layer 1112 are not connected.

In some examples, with reference to FIG. 3, the first semiconductor structure 101 further includes a first dielectric layer 131 between the wall structure 120 and the semiconductor layer 111. The wall structure 120 includes: a second dielectric layer 121, a conductive layer 122 and a third dielectric layer 123 stacked in z direction, wherein the second dielectric layer 121 is located on a side of the conductive layer 122 close to the first end in z direction, and the size of the second dielectric layer 121 in x direction is smaller than the size of the conductive layer 122 in x direction.

The wall structure 120 may include an insulating material. The wall structure 120 provides an attachment surface for the semiconductor layer 111 and serves as a mechanic support. Alternatively, the wall structure 120 may include a conductive material as a back gate connected to a low potential such as ground or negative voltage to improve the coupling effect between adjacent transistors 110, reduce the parasitic capacitance between adjacent first semiconductor layer 111 and second semiconductor layer 1112, and increase the stability of device. For example, the wall structure 120 includes the second dielectric layer 121, the conductive layer 122 and the third dielectric layer 123 stacked in turn, and the conductive layer 122 serves as a back gate connected to ground or negative voltage. A first dielectric layer 131 is further disposed between one side of the wall structure 120 and the semiconductor layer 111 for electrically isolating the conductive layer 122 and the semiconductor layer 111. The third dielectric layer 123 functions to electrically isolate the semiconductor layer 111 and the conductive layer 122 on its two sides in z direction. The second dielectric layer 121 functions to electrically isolate the conductive layer 122 and other conductive devices on its two sides in z direction, such as the conductive layer 122 and electrodes of the capacitive structure 140. Materials for the first dielectric layer 131, the second dielectric layer 121 and the third dielectric layer 123 may include, but not limited to insulating materials such as silicon oxide, silicon nitride, silicon oxynitride, or aluminum oxide, etc. The second dielectric layer 121 in FIG. 3 has a size in x direction smaller than that of the conductive layer 122 and smaller than that of the third dielectric layer 123. The constituting materials for the second dielectric layer 121 and the third dielectric layer 123 are different to have different etching selection ratio, which facilitates reducing the size of the second dielectric layer 121 in x direction by etching process in fabrication process without etching the third dielectric layer 123. The sizes of the second dielectric layer 121, the conductive layer 122 and the third dielectric layer 123 in x direction in FIG. 2 may be equal or substantially equal with a certain error and the constituting materials for the second dielectric layer 121 and the third dielectric layer 123 may be the same.

In an example, the conductive layer 122 may include, but not limited to conductive materials such as tungsten, gold, silver, copper, chromium, nickel, titanium, aluminum, and titanium nitride.

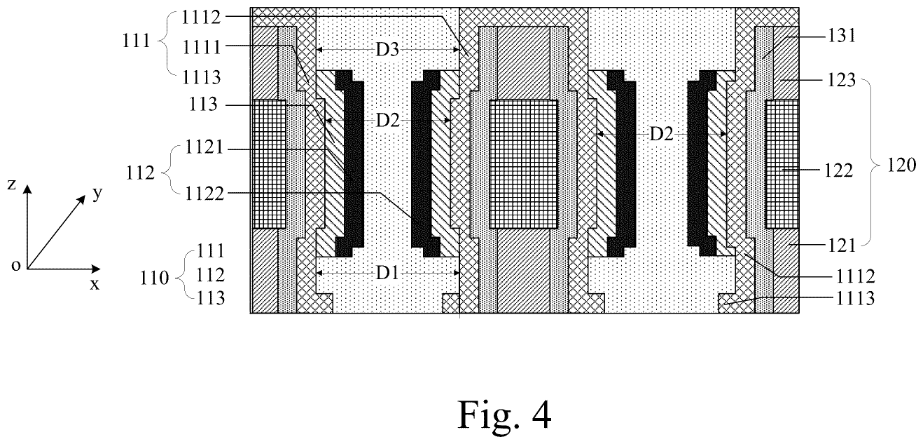

In some examples, with reference to FIG. 4, the second end of the first semiconductor layer 1111 has a third distance (denoted as D3) from the second end of the second semiconductor layer 1112 in x direction. The third distance D3 is greater than the second distance D2. The second end of the first semiconductor layer 1111 extends towards the wall structure 120 in x direction such that the third distance is greater than the second distance, thereby increasing the distance between adjacent first semiconductor layer 1111 and second semiconductor layer 1112 and reducing interference between adjacent semiconductor layers 111.

In some examples, with reference to FIG. 4, the size of the third dielectric layer 123 in x direction is smaller than the size of the conductive layer 122 in x direction. The size of the third dielectric layer 123 in x direction may be equal or not equal to the size of the second dielectric layer 121 in x direction, and the third dielectric layer 123 may have the same constituting material as the second dielectric layer 121 so as to have the same etching selection ratio, which facilitates reducing the sizes of the third dielectric layer 123 and the second dielectric layer 121 in x direction by the same etching process in fabrication process, thereby reducing manufacturing costs.

In some examples, with reference to FIGS. 3 and 4, at least one of the first end or second end of the semiconductor layer 111 extends towards the wall structure 120 in x direction, which at least reduces the gap between a part of the semiconductor layer 111 and the conductive layer 122 serving as the back gate, enhances the control capability of the back gate, and reduces interference between the semiconductor layers 111 on two sides of the conductive layer 122.

In some examples, with reference to FIGS. 3 and 4, considering adjacent first gate layer 1121 and second gate layer 1122 as an example, the first gate layer 1121 is located on right side of the wall structure 120 and corresponds to the first semiconductor layer 1111, and the second gate layer 1122 is located on left side of the wall structure 120 and corresponds to the second semiconductor layer 1112. At least one of the first end or second end of the first gate layer 1121 extends towards its corresponding first semiconductor layer 1111, and at least one of the first end or second end of the second gate layer 1122 extends towards its corresponding second semiconductor layer 1112.

In some examples, with reference to FIGS. 3 and 4, the semiconductor layer 111 surrounds two sides of the wall structure 120 disposed oppositely in x direction and surrounds one side of the wall structure 120 in z direction. The semiconductor layer 111 includes two first ends exposing another side of the wall structure 120 in z direction. The semiconductor layer 111 provides channels for the two transistors 110 adjacent in x direction.

The second end of the first semiconductor layer 1111 and the second end of the second semiconductor layer 1112 may be a continuous structure, and one semiconductor layer 111 may cover one side of the wall structure 120 in z direction and two surfaces of the wall structure 120 disposed oppositely in x direction. One semiconductor layer 111 may include one first semiconductor layer 1111 and one second semiconductor layer 1112. Second ends of the first semiconductor layer 1111 and the second semiconductor layer 1112 are partially connected by the semiconductor layer 111 extending in x direction. The first semiconductor layer 1111 and the second semiconductor layer 1112 correspond to two transistors 110 respectively. Alternatively, the cross-sectional shape of the semiconductor layer 111 in xoz plane may be U or inverted U shape including two first ends and one second end covering the top surface of wall structure 120 with the two first ends enclosing an opening exposing the wall structure 120. One semiconductor layer 111 corresponds to two transistors 110, with the first semiconductor layer 1111 and the second semiconductor layer 1112 extending in z direction respectively. The part of the semiconductor layer 111 that covers the wall structure 120 in z direction provides a large and smooth contacting surface for bit lines 114 to reduce the contact gaps between bit lines 114 and the semiconductor layer 111, improve the stability of devices, and omit the process step of removing semiconductor layer 111 to expose the wall structure 120, thereby reducing the manufacturing costs.

In some examples, with reference to FIGS. 3 and 4, the first end includes a protrusion 1113 extending in a direction away from the wall structure 120. An end of the first end that is farthest from the second end has the protrusion 1113 that may extend in x direction away from the wall structure 120. The protrusion 1113 may be coupled with the capacitive structure 140 to increase the coupling area between the first end and the capacitive structure 140 and provide a smooth contact surface, and improve coupling stability. In some examples, the protrusion 1113 is the remainder resulted from etching and breaking the semiconductor material between the adjacent wall structures 120 in z direction when forming the semiconductor layer 111. In some examples, there may not be the protrusion 1113, or the size of the protrusion 1113 in x direction is a small and not easily visible.

In some examples, the constituting material for the semiconductor layer 111 includes indium gallium zinc oxide IGZO. The IGZO material may include oxide of elements such as indium, gallium and zinc and have excellent semiconductor properties. The addition of indium and gallium may improve electron mobility of the semiconductor material, and realize lower operating voltage and lower power consumption than traditional semiconductor materials such as silicon; and the addition of zinc facilitates improving stability of semiconductor material. The IGZO material may realize deposition of semiconductor layer 111, may control the film thickness, crystal type and film topology of the semiconductor layer 111 by controlling deposition process parameters, and facilitates simplifying the fabrication process while improving yield of the semiconductor layer 111. The IGZO material may allow the semiconductor layer 111 and metal parts such as the first electrode 141 to directly contact and be couple, thereby reducing contact resistance.

In some examples, with reference to FIGS. 3 and 4, the first semiconductor structure 101 further includes a gate dielectric layer 113 between the semiconductor layer 111 and the gate layer 112. The gate layer 112 may include a conductive single-layered structure, such as tungsten. The gate layer 112 may also include a conductive multiple-layered structure, e.g., including a first sub gate layer and a second sub gate layer. The first sub gate layer is located between the gate dielectric layer and the second sub gate layer. The size of the first sub gate layer in x direction is smaller than the thickness of the second sub gate layer. The first sub gate layer is configured to enhance the adhesion between the gate dielectric layer and the second sub gate layer. In an example, the first sub gate layer may include titanium nitride, and the second sub gate layer may include tungsten. In some examples, there is provided a filling layer between the adjacent wall structures 120 for electrically isolating the gate and the semiconductor layer 111 adjacent. The filling layer includes the same material as the gate dielectric layer 113, in which case there may be no evident physical boundary between the filling layer and the gate dielectric layer 113.

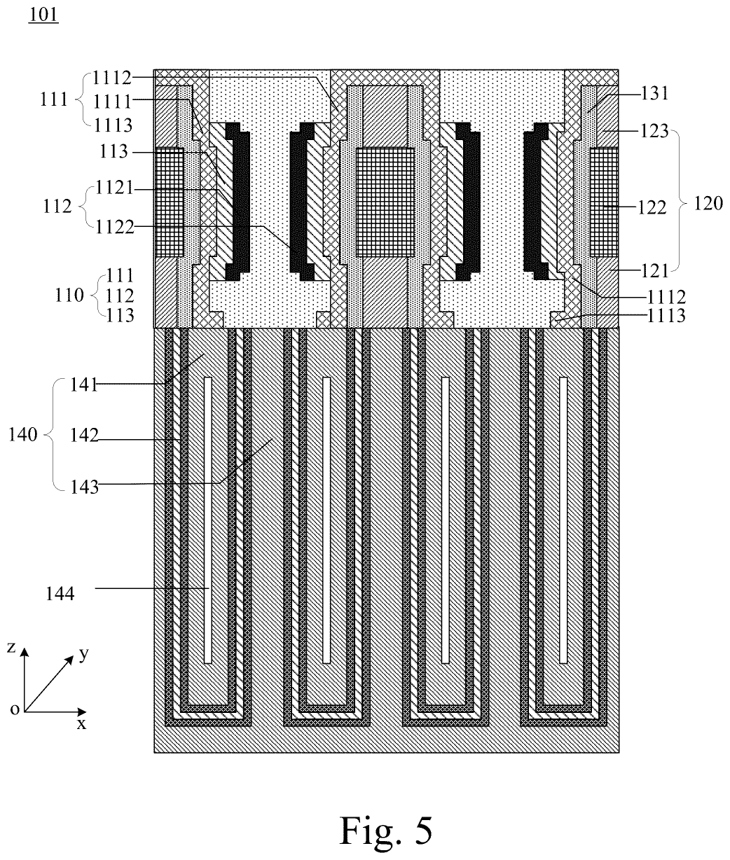

In some examples, with reference to FIG. 5, the first semiconductor structure 101 further includes a capacitive structure 140 located on a side of the semiconductor layer 111 close to the first end and coupled with the first end. The capacitive structure 140 includes two conductive electrodes and a dielectric layer between the two conductive electrodes for electrical isolation. One electrode of the capacitive structure 140 is coupled with the first end of the semiconductor layer 111 directly or via a conductive structure. The specific structure of the capacitive structure 140 is not limited in examples of the present disclosure. At least one electrode of the capacitive structure 140 may extend in z direction.

In some examples, with regard to FIG. 5, the capacitive structure 140 includes a first electrode 141, a fourth dielectric layer 142 and a second electrode 143, the fourth dielectric layer 142 being located between the first electrode 141 and the second electrode 143, wherein the first electrode 141 is coupled with the first end and a plurality of capacitive structures 140 are coupled via the second electrodes 143. In some examples, with reference to FIG. 5, the first electrode 141 extends in z direction and the first electrode 141 includes air gap 144.

The first electrode 141 extends in z direction and is coupled with the first end of the semiconductor layer 111 by direct contacting with each other or via a connection or contact. The first electrode 141 may include air gap 144 for reducing stress concentration to reduce deformation of device. The fourth dielectric layer 142 may surround side walls of the first electrode 141 and an end of the first electrode 141 not coupled with the first end and the second electrode 143 may surround the fourth dielectric layer 142. A part of the fourth dielectric layer 142 may extend in z direction. A part of the second dielectric layer 143 extends in z direction and is located between adjacent two first electrodes 141. The other part of the second electrode 143 extends in x direction and covers the fourth dielectric layer 142 in z direction. A plurality of capacitive structures 140 may be coupled via part of the second electrode 143 extending in x direction. The part of the second electrodes 143 extending in x direction connects a plurality of capacitive structures 140 and may be configured to be grounded or applied with other voltages such as Vdd/2.

In some examples, with reference to FIG. 5, the first electrode 141 may include a first connection layer and a conductive pillar. The first connection layer surrounds the conductive pillar and is located between the conductive pillar and the fourth dielectric layer 142, which is configured to enhance the adhesion between the fourth dielectric layer 142 and the conductive pillar. A second connection layer is disposed between the fourth dielectric layer 142 and the second electrode 143, which can enhance the adhesion between the fourth dielectric layer 142 and the second electrode 143. In an example, the first electrode 141 and the second electrode 143 may include conductive materials such as tungsten, gold, silver, copper, chromium, nickel, titanium or aluminum. The first connection layer and the second connection layer may include, but not limited to titanium nitride.

In some examples, with reference to FIG. 6, the first semiconductor structure 101 further includes a bit line 114 located on a side of the semiconductor layer 111 close to the second end and coupled with the second end.

In an example, the second electrode 143 is connected to the common voltage. A voltage is applied via a bit line 114 and a gate layer 112 to select the semiconductor layer 111 at the intersection between the bit line 114 and the gate layer 112. A gate layer 112 applies a turn-on voltage to turn on the semiconductor layer 111 and supply voltage to a first electrode 141. Now a capacitive structure 140 is selected to perform read, write or update operation. An interconnection layer is disposed on a side of the bit line 114 away from the capacitive structure 140 for powering the bit line 114 or structures such as gate layer 112, thereby enabling leading out power supply or electrical signal for the first semiconductor structure 101.

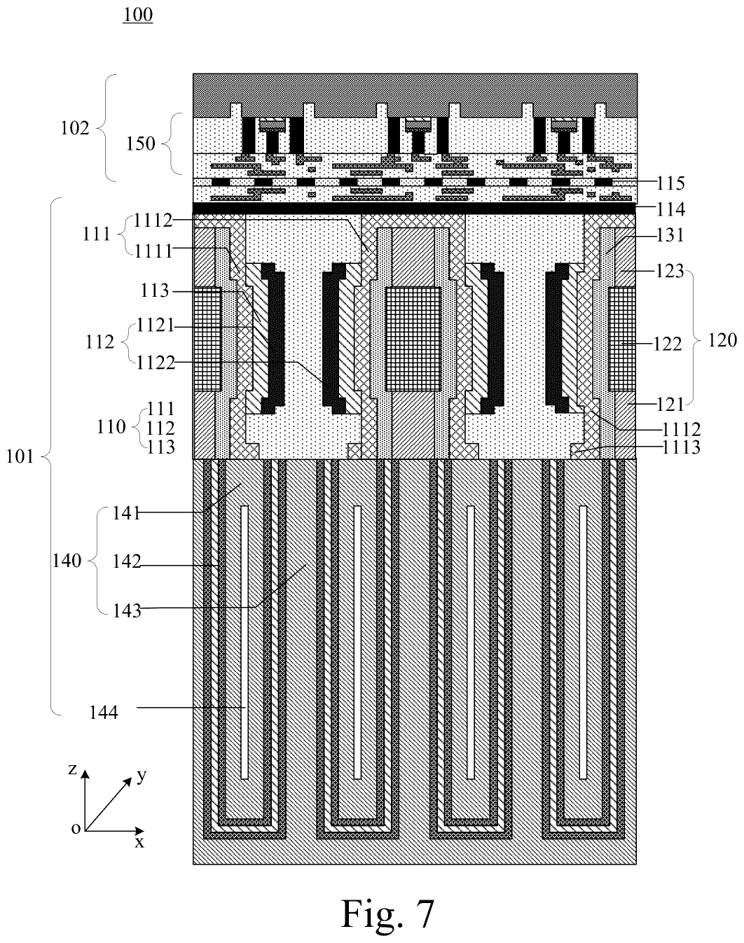

In some examples, with reference to FIG. 7, the semiconductor device 100 further includes a second semiconductor structure 102 located on a side of the bit line 114 away from the semiconductor layer 111, the second semiconductor structure 102 including a peripheral circuit 150. The second semiconductor structure 102 and the first semiconductor structure 101 are bonded. The bonding may include for example hybrid bonding.

Before bonding, the surfaces to be bonded of the first semiconductor structure 101 and the second semiconductor structure 102 have a first bonding contact and a second bonding contact respectively, which leading out the electrical signals of the semiconductor structures to the surfaces to be bonded respectively. The bonding contacts 115 may include structures such as pads, conductive plugs. The surfaces to be bonded of the first semiconductor structure 101 and the second semiconductor structure 102 are bonded with the interface between the two surfaces to be bonded serving as the bonding interface. The first bonding contact and the second bonding contact are brought into contact and bonded at the bonding interface to realize electrical signal interconnection between the first semiconductor structure 101 and the second semiconductor structure 102. There may not be any physical boundary between the first bonding contact and the second bonding contact after bonding. They may be considered as the bonding contact 115 in the drawing which extends through the bonding interface. The part of the bonding contact 115 located at the first semiconductor structure 102 is the first bonding contact before bonding, and the part of the bonding contact 115 located at the second semiconductor structure 102 is the second bonding contact before bonding. Considering the gate layer 112, the bit line 114 and the second electrode 143 as an example, the gate layer 112, the bit line 114 and the second electrode 143 may lead out the electrical signals to the bonding contact 115 to be coupled with the peripheral circuit 150 via the contact structures respectively. An interconnection layer may be disposed between the bit line 114 and the bonding contact 115 to lead out the signals from the first semiconductor structure 101 to be interconnected with electrical signals of the peripheral circuit 150.

In an example, the peripheral circuit 150 may include, but not limited to a sense amplifying circuit, a row decoding circuit, a column decoding circuit, a voltage generating circuit etc. The sense amplifying circuit is coupled with the bit line 114 and can be configured to capture small voltage fluctuations on the bit line 114 and restore the capacitor voltage of the memory cell locally depending on the voltage fluctuations. The sense amplifying circuit may include a latch that may latch the restored capacitor voltage values such that information stored in the memory cell is transferred from the capacitor to the amplifying circuit. The sense amplifying circuit may include a differential sense amplifying circuit coupled with two bit lines 114 and functions with one selected bit line 114 and one complementary bit line 114 serving as reference line to detect and amplify voltage difference between the pair of bit lines 114. The row decoding circuit is configured to row address the memory array and apply an operation voltage on the word line. The column decoding circuit is configured to column address the memory array and apply or receive a bit line voltage. The voltage generating circuit generates desired high and low voltages for devices.

In some examples, the second semiconductor structure 102 and the first semiconductor structure 101 are not secured by bonding and no bonding contact 115 may be disposed between the first semiconductor structure 101 and the second semiconductor structure 102.

According to some aspects of an example of the present disclosure, FIG. 3 provides a semiconductor device including: a semiconductor layer 111 extending at least in the first direction (z direction) and having a first end and a second end disposed oppositely in the first direction; a wall structure 120 extending in a second direction (y direction), the semiconductor layer 111 being located on two sides of the wall structure 120 disposed oppositely in a third direction (x direction), the third direction intersecting the second direction, the plane constituted by the third direction and the second direction intersecting the first direction; a first dielectric layer 131 between the wall structure 120 and the semiconductor layer 111; wherein the wall structure 120 includes a second dielectric layer 121, a conductive layer 122 and a third dielectric layer 123 stacked in the first direction, the second dielectric layer 121 is located on a side of the conductive layer 122 close to the first end in the first direction; and the size of the second dielectric layer 121 in the third direction is smaller than the size of the conductive layer 122 in the third direction.

In some examples, with reference to FIG. 4, the size of the third dielectric layer 123 in x direction is smaller than the size of the conductive layer 122 in x direction.

In some examples, with reference to FIGS. 3 and 4, the semiconductor layer 111 surrounds two sides of the wall structure 120 disposed oppositely in x direction and surrounds one side of the wall structure 120 in z direction. The semiconductor layer 111 includes two first ends exposing another side of the wall structure 120 in z direction.

In some examples, with reference to FIGS. 3 and 4, the first end includes a protrusion 1113 extending in a direction away from the wall structure 120.

In some examples, with reference to FIGS. 3 and 4, the semiconductor layer 111 includes a first semiconductor layer 1111 and a second semiconductor layer 1112 disposed adjacently in x direction. The semiconductor device further includes a gate layer 112 extending in y direction and located on two sides of the wall structure 120 disposed oppositely in x direction, the gate layer 112 including a first gate layer 1121 and a second gate layer 1122 disposed adjacently in x direction and between the first semiconductor layer 1111 and the second semiconductor layer 1112; and a gate dielectric layer 113 located between the semiconductor layer 111 and the gate layer 112.

In some examples, with reference to FIGS. 5 and 6, the semiconductor device further includes a capacitive structure 140 located on a side of the semiconductor layer 111 close to the first end and coupled with the first end.

In some examples, with regard to FIGS. 5 and 6, the capacitive structure 140 includes a first electrode 141, a fourth dielectric layer 142 and a second electrode 143, the fourth dielectric layer 142 being located between the first electrode 141 and the second electrode 143, wherein the first electrode 141 is coupled with the first end and a plurality of capacitive structures 140 are coupled via the second electrodes 143.

In some examples, with reference to FIGS. 5 and 6, the first electrode 141 extends in the first direction and the first electrode 141 includes air gap 144.

In some examples, with reference to FIG. 6, the semiconductor device further includes a bit line 114 located on a side of the semiconductor layer 111 close to the second end and coupled with the second end.

In some examples, with reference to FIG. 7, the wall structure 120, the semiconductor layer 111 and the bit line 114 are located in the first semiconductor structure 101; and the semiconductor device 100 further includes a second semiconductor structure 102 located on a side of the bit line 114 away from the semiconductor layer 111 and including a peripheral circuit 150. The second semiconductor structure 102 and the first semiconductor structure 101 are bonded.

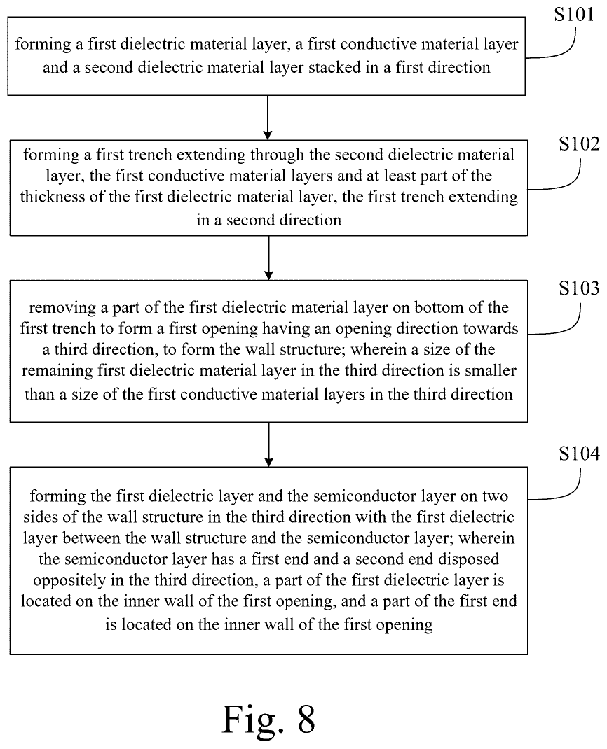

According to some aspects of examples of the present disclosure, there is provided a fabrication method of a semiconductor device 100 including forming the first semiconductor structure 101. Referring to FIG. 8, the method of forming the first semiconductor structure 101 includes:
forming a first dielectric material layer, a first conductive material layer and a second dielectric material layer stacked in a first direction;
forming a first trench extending through the second dielectric material layer, the first conductive material layers and at least a part of thickness of the first dielectric material layer and extending in the second direction;
removing a part of the first dielectric material layer on bottom of the first trench to form a first opening having an opening direction toward a third direction, thereby forming a wall structure; wherein a size of the remaining first dielectric material layer in the third direction is smaller than a size of the first conductive material layers in the third direction; the third direction intersects the second direction, and a plane constituted by the third direction and the second direction intersects the first direction;
forming the first dielectric layer and the semiconductor layer on two sides of the wall structure in the third direction with the first dielectric layer between the wall structure and the semiconductor layer; wherein the semiconductor layer has a first end and a second end disposed oppositely in the third direction, a part of the first dielectric layer is located on the inner wall of the first opening, and a part of the first end is located on the inner wall of the first opening.

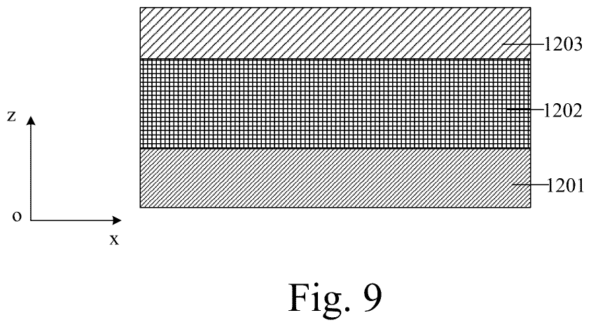

In an example, with reference to FIG. 9, the first dielectric material layer 1201, the first conductive material layers 1202 and the second dielectric material layer 1203 are formed sequentially in z direction, which may be formed on a structure such as substrate and base substrate. In an example, the forming processes for the above-described material layers may include, but not limited to deposition processes that may include, but not limited to chemical vapor deposition (CVD), physical vapor deposition (PVD) and atomic layer deposition (ALD).

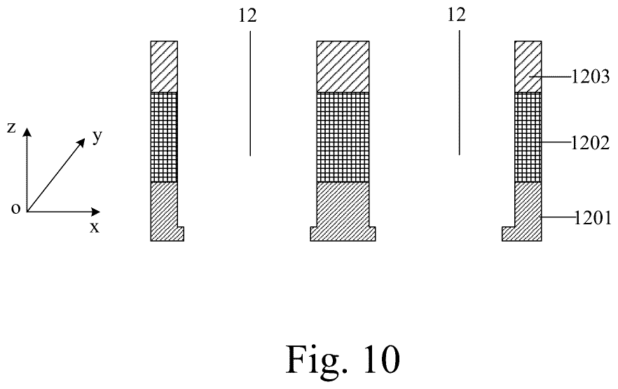

With reference to FIG. 10, the first trench 12 extending in y direction is formed by etching. The first trench 12 extends in z direction through the second dielectric material layer 1203, the first conductive material layers 1202 and the first dielectric material layer 1201. The first trench 12 may extend through only a part of thickness of the first dielectric material layer 1201 and the remaining first dielectric material layer 1201 may be removed in subsequent etching.

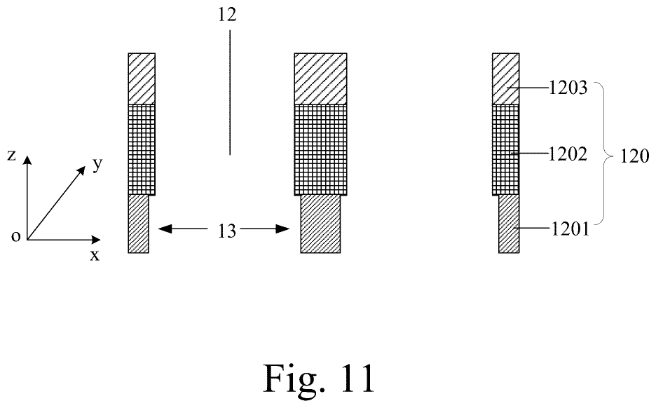

With reference to FIG. 11, a part of first dielectric material layer 1201 on the bottom of the first trench 12 is etched off in x direction to reduce the size of the first dielectric material layer 1201 in x direction and form a first opening 13 having an opening direction toward x direction. The remaining first dielectric material layer 1201, the first conductive material layers 1202 and the second dielectric material layer 1203 form the wall structure 120. The remaining first dielectric material layer 1201 forms the second dielectric layer 121 shown in FIGS. 3 to 7. The remaining first conductive material layers 1202 forms the conductive layer 122. The remaining second dielectric material layer 1203 forms the third dielectric layer 123. In the etching process in FIG. 11, the first dielectric material layer 1201 and the second dielectric material layer 1203 have different materials such that the second dielectric material layer 1203 may not or substantially not be etched while etching the first dielectric material layer 1201 and the remaining first dielectric material layer 1201 has a size in x direction smaller than a size of the remaining first conductive material layer 1202 in x direction. The etching process may include, but not limited to dry etching, wet etching or any combination thereof.

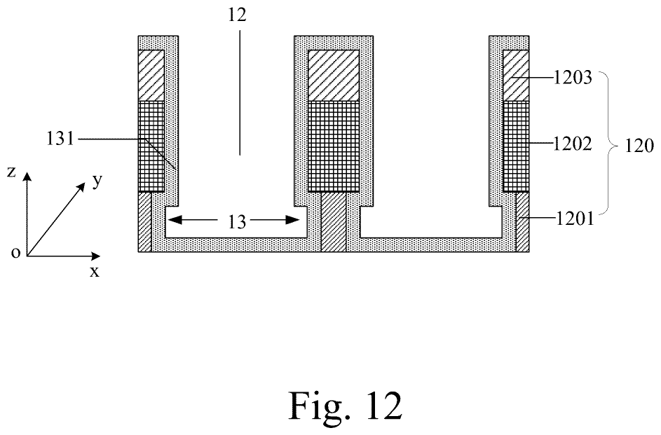

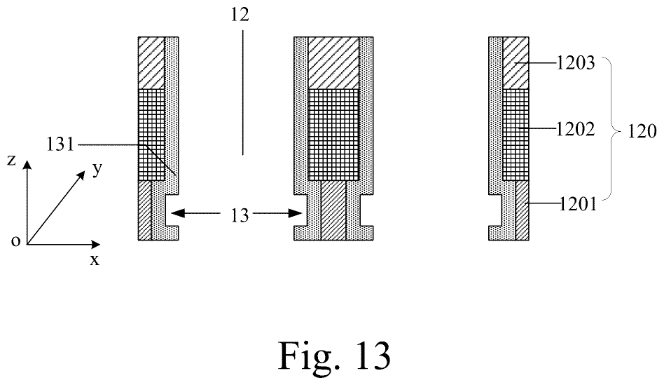

With reference to FIG. 12, based on the first trench 12 including the first opening 13 as shown in FIG. 11, a first dielectric layer 131 is formed which covers two sides of the wall structure 120 in x direction, and covers the second dielectric material layer 1203 and the first dielectric layer 131 on bottom of the first trench 12 in z direction. With reference to FIG. 13, the first dielectric layer 131 on the second dielectric material layer 1203 and on the bottom of the first trench 12 is etched, and the first dielectric layer 131 on sides of the wall structure 120 remains. A part of the first dielectric layer 131 is located on inner wall of the first opening 13. A semiconductor layer 111 is formed on the first dielectric layer 131 on two sides of the wall structure 120 with a part of the semiconductor layer 111 located in the first opening 13. The first end of the semiconductor layer 111 is located on the bottom of the first trench 12 with at least a portion of the first end located in the first opening 13. In FIG. 13, the first dielectric material layer 1201 that has not been completely penetrated through in the previous process may be penetrated while penetrating the first dielectric layer 131.

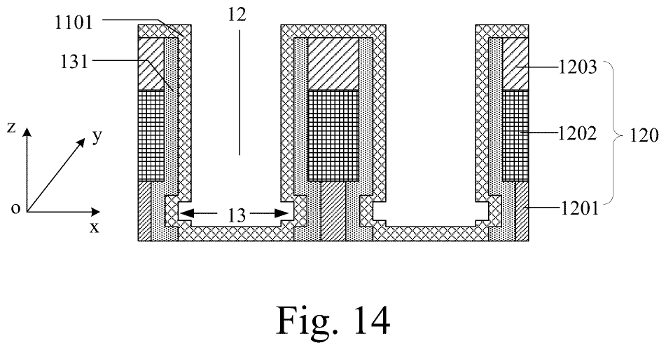

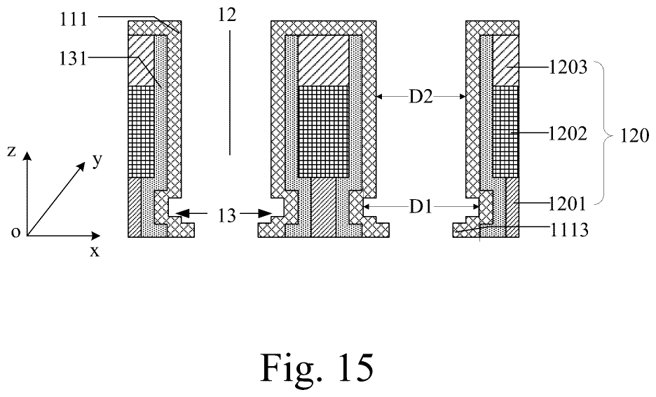

In some examples, the method of forming the semiconductor layer 111 includes: with reference to FIG. 13, forming the first dielectric layer 131 on two sides of the first trench 12 in x direction; with reference to FIG. 14, forming the semiconductor material layer 1101 covering the first dielectric layer 131 in x direction and covering the bottom of the first trench 12 in z direction; and with reference to FIG. 15, penetrating the semiconductor material layer 1101 on the bottom of the first trench 12 in z direction to form the semiconductor layer 111 with the first end of the semiconductor layer 111 located on the bottom of the first trench 12 and at least a portion of the first end located in the first opening 13.

In some examples, with reference to FIG. 14, the semiconductor material layer 1101 further covers the remaining second dielectric material layer 1203 in z direction. In some examples, with reference to FIG. 15, the method of forming the semiconductor layer 111 further includes: forming a protrusion 1113 by the remainder of the semiconductor material layer 1101 while penetrating through the semiconductor material layer 1101; wherein the protrusion 1113 extends in a direction away from the wall structure 120.

With reference to FIG. 14, while depositing the semiconductor material layer 1101, the semiconductor material layer 1101 covers the first dielectric layer 131 in x direction, further covers the second dielectric material layer 1203 in z direction. The semiconductor material layer 1101 on the bottom of the first trench 12 is etched through in z direction to form a separate semiconductor layer 111 for convenience of controlling by the gate layer 112 separately. The part of semiconductor layer 111 that covers the second dielectric material layer 1203 in z direction may remain to provide a large area and smooth contacting surface for subsequent bit lines 114 to reduce the contact gaps between bit lines 114 and the semiconductor layer 111, improve the stability of devices, and omit the process step of removing semiconductor layer 111 to expose the wall structure 120, thereby reducing the manufacturing costs. While penetrating through the semiconductor material layer 1101 on the bottom of the first trench 12 in z direction, the remaining semiconductor material layer 1101 forms a protrusion 1113. The protrusion 1113 may extend in x direction away from the first dielectric layer 131. The protrusion 1113 may be coupled with the capacitive structure 140 to increase the contact area between the first end and the capacitive structure 140 and provide a smooth contact surface, and improve coupling stability.

In some examples, the part of the semiconductor layer 111 that covers the second dielectric material layer 1203 in z direction may be removed such that electron migration is reduced in the first semiconductor layer 1111 and the second semiconductor layer 1112 on opposite two sides of the same wall structure 120 in x direction, thereby improving the stability of the device. In an example, the removing processes include, but not limited to etching process, chemical mechanical polishing process or any combination thereof.

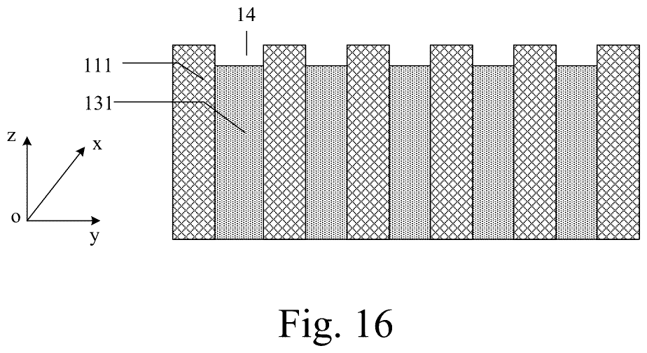

In some examples, with reference to FIG. 16, the method of forming the semiconductor layer 111 further includes: forming a second trench 14 extending through the semiconductor material layer 1101 in z direction and extending in x direction. The second trench 14 may have an inverted U shaped cross section in xoz plane. The second trench 14 includes a portion extending in z direction and a portion extending in x direction. The second trench 14 exposes the first dielectric layer 131 in z direction and exposes the first dielectric layer 131 in x direction. The second trench 14 divides the semiconductor material layer 1101 to form semiconductor layers 111 arranged at intervals in y direction as shown in FIG. 16 with areas between semiconductor layers 111 adjacent in y direction exposing the first dielectric layer 131.

In some examples, the method for forming the first semiconductor structure 101 further includes: forming a gate dielectric layer 113 and a second conductive material layer 1102 at least covering the semiconductor layer 111 in x direction and covering the bottom of the first trench 12 in z direction; and penetrating through at least the second conductive material layer 1102 in z direction to form the gate layer 112.

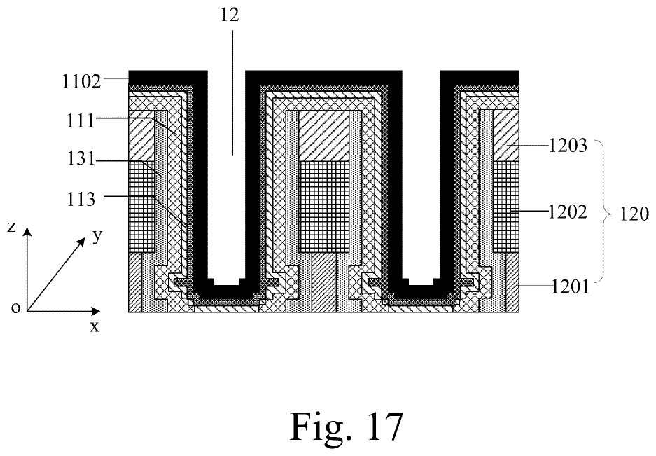

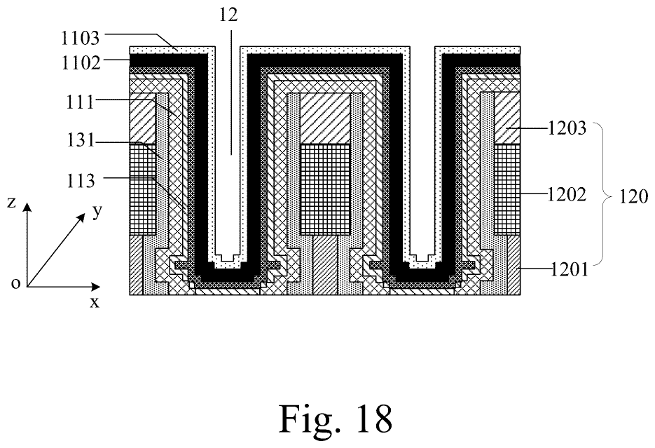

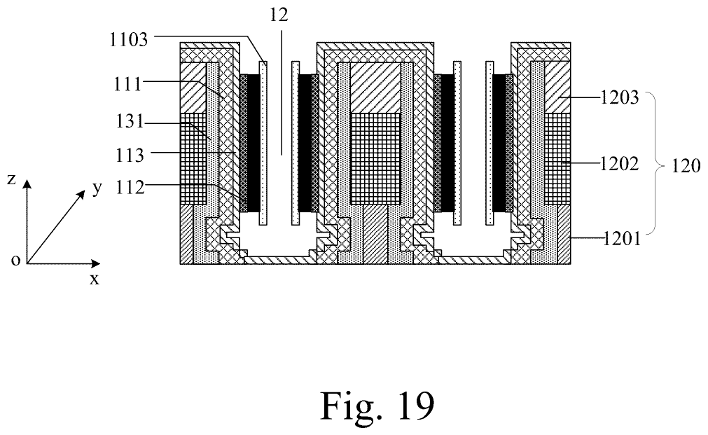

With reference to FIGS. 17 and 18, based on the first trench 12 shown in FIG. 15, the gate dielectric layer 113, the second conductive material layer 1102 and a protection layer 1103 covering the semiconductor layer 111 in x direction and z direction are formed sequentially. With reference to FIG. 19, at least the protection layer 1103 and the second conductive material layer 1102 on the bottom of the first trench 12 are penetrated in z direction and the remaining second conductive material layer 1102 forms the gate layer 112. The protection layer 1103 is configured to block etchant such that the remaining size of the gate layer 112 in z direction may be adjusted and the protection layer 1103 may include silicon nitride, silicon oxide or silicon oxynitride. In FIG. 17, the second conductive material layer 1102 may include a first sub conductive material layer and a second sub conductive material layer, in which the first sub conductive material layer enhances the adhesion between the gate dielectric layer 113 and the second sub conductive material layer. In an example, the first sub conductive material layer may include titanium nitride, and the second sub conductive material layer may include tungsten. In FIG. 19, the gate dielectric layer 113 located on the bottom of the first trench 12 may not be penetrated.

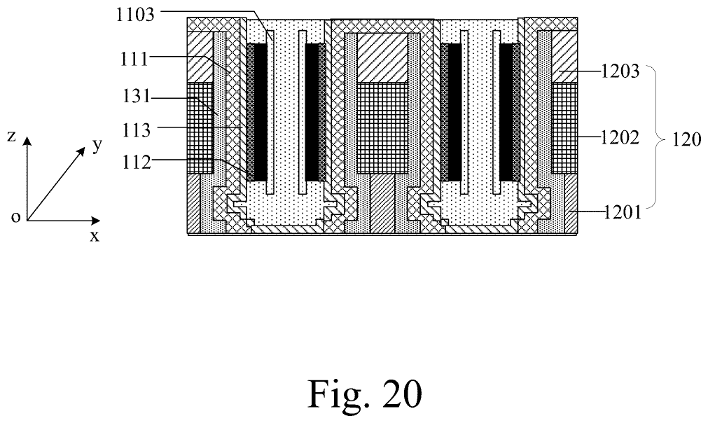

With reference to FIG. 20, the remaining space of the first trench 12 is filled with an insulating material and the gate dielectric layer 113 on surface of the semiconductor layer 111 on the second end side is planarized to expose the semiconductor layer 111. The filling process may include spin-coating and the planarization may include chemical mechanical polishing. The insulating material and the protection layer 1103 may include the same material such as silicon oxide such that there may not be any evident physical boundaries between the same film materials.

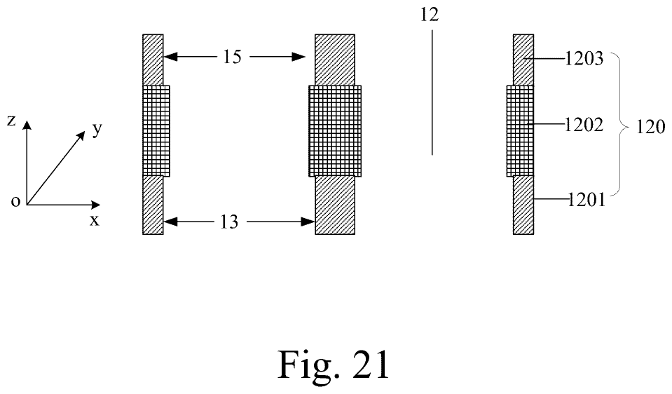

In some examples, with reference to FIG. 21, the method of forming the wall structure 120 further includes: removing a part of second dielectric material layer 1203 at the opening side of the first trench 12 to form a second opening 15 having an opening direction toward x direction; wherein the size of the remaining second dielectric material layer 1203 in x direction is smaller than the size of the first conductive material layers 1202 in x direction; a part of the first dielectric layer 131 is located on inner wall of the second opening 15 and a part of the second end is located on inner wall of the second opening 15. The constituting materials for the second dielectric material layer 1203 and the first dielectric material layer 1201 in FIG. 21 may be the same. It is possible to reduce the size of the second dielectric material layer 1203 and the first dielectric material layer 1201 at the same time by etching in x direction, form the first opening 13 in the bottom of the first trench 12 and form the second opening 15 in the open end of the first trench 12. A part of the subsequently formed first dielectric layer 131 is on inner wall of the second opening 15. A part of the second end is located on the first dielectric layer 131 in the second opening 15. The formed first dielectric layer 131 and the semiconductor layer 111 may be as shown in FIG. 4.

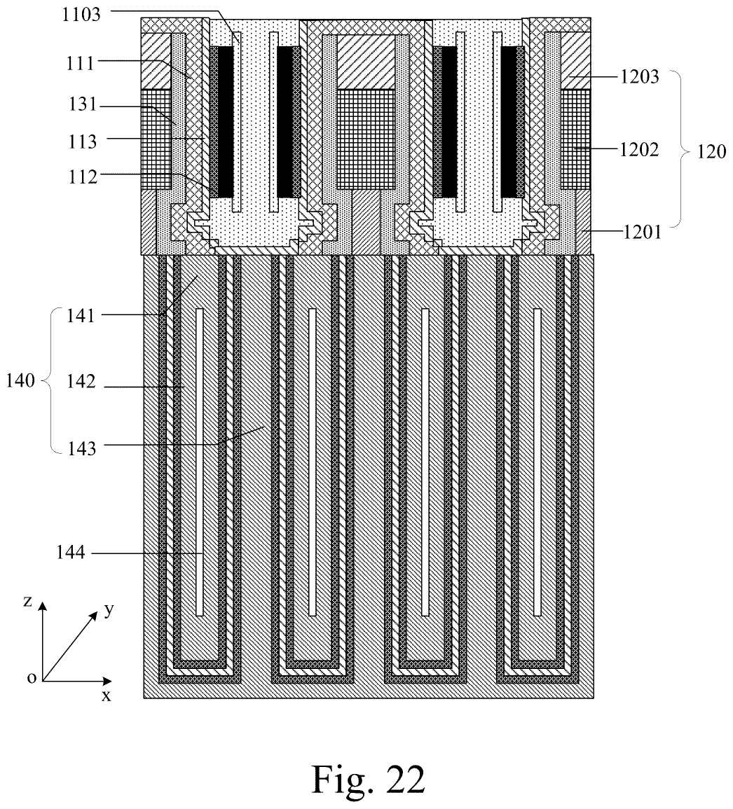

In some examples, with reference to FIG. 22, the method of forming the first semiconductor structure 101 further includes: forming a capacitive structure 140 on a side of the semiconductor layer 111 close to the first end, an electrode of the capacitive structure 140 close to the first end being coupled with the first end. The capacitive structure 140 may include a first electrode 141, a fourth dielectric layer 142 and a second electrode 143, the fourth dielectric layer 142 being located between the first electrode 141 and the second electrode 143, wherein the first electrode 141 is coupled with the first end and a plurality of capacitive structures 140 are coupled via the second electrodes 143. The first electrode 141 extends in z direction and is coupled with the first end of the semiconductor layer 111 by direct contact or via a connection or a contact. The first electrode 141 may include air gap 144 for reducing stress concentration to reduce deformation of device. The fourth dielectric layer 142 may surround the first electrode 141 and the second electrode 143 may surround the fourth dielectric layer 142. A part of the fourth dielectric layer 142 may extend in z direction. A part of the second dielectric layer 143 extends in z direction and is located between adjacent two first electrodes 141. The other part of the second electrode 143 extends in x direction and covers the fourth dielectric layer 142 in z direction. A plurality of the capacitive structures 140 may be coupled via the part of the second electrode 143 extending in x direction. The part of the second electrode 143 extending in x direction connect the plurality of the capacitive structures 140 in series and may be configured to be grounded or applied with other voltages such as Vdd/2. The first electrode 141 may include a first connection layer and a conductive pillar. The first connection layer surrounds the conductive pillar and is located between the conductive pillar and the fourth dielectric layer 142, the first connection layer being configured to enhance the adhesion between the fourth dielectric layer 142 and the conductive pillar.

The capacitive structure 140 may be formed prior to the structure shown in FIG. 20 or before forming the semiconductor layer 111. Alternatively, a part of the capacitive structure 140 such as the first electrode 141 is formed first, and the transistor 110 structure shown in FIGS. 3 to 5 or FIG. 20 is formed at one end of the first electrode 141, and then the second electrode 143 is formed.

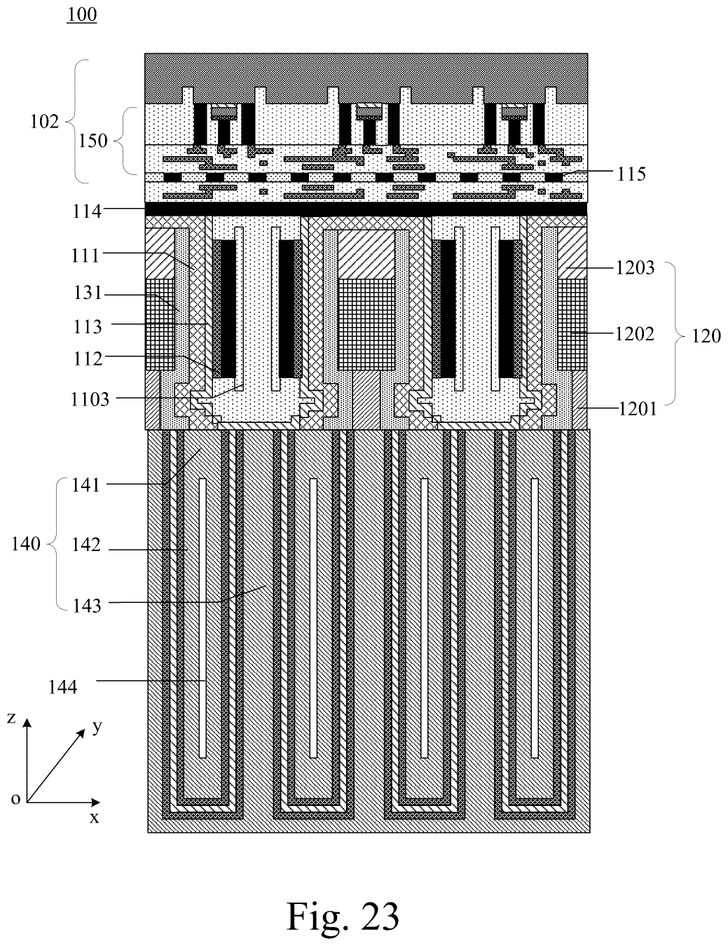

In some examples, with reference to FIGS. 6 and 23, the method of forming the first semiconductor structure 101 further includes forming a bit line 114 on a side of the semiconductor layer 111 close to the second end, the bit line 114 being coupled with the second end.

In some examples, with reference to FIGS. 7 and 23, the fabrication method of the semiconductor device 100 further includes: bonding a second semiconductor structure 102 on a side of the bit line 114 away from the semiconductor layer 111, the second semiconductor structure 102 including a peripheral circuit 150.

Before bonding, the first semiconductor structure 101 and the second semiconductor structure 102 have a first bonding contact and a second bonding contact on their surfaces to be bonded respectively. Electrical signals of the semiconductor structures are led out to the surfaces to be bonded respectively. The bonding contacts 115 may include structures such as pads, conductive plugs. The surfaces to be bonded of the first semiconductor structure 101 and the second semiconductor structure 102 are bonded with the interface between the two surfaces to be bonded serving as the bonding interface. The first bonding contact and the second bonding contact are brought into contact and bonded at the bonding interface to enable the electrical signal interconnection between the first semiconductor structure 101 and the second semiconductor structure 102. There may not be any physical boundary between the first bonding contact and the second bonding contact after bonding. They may be considered as the bonding contact 115 in the figure which extends through the bonding interface. Considering the gate layer 112, the bit line 114 and the second electrode 143 as an example, the gate layer 112, the bit line 114 and the second electrode 143 may lead out electrical signals to the bonding contact 115 to be coupled with the peripheral circuit 150 via the contact structures respectively.

According to some aspects of examples of the present disclosure, there is provided a memory system including a memory device including a semiconductor device and a memory controller coupled with and controlling the memory device.

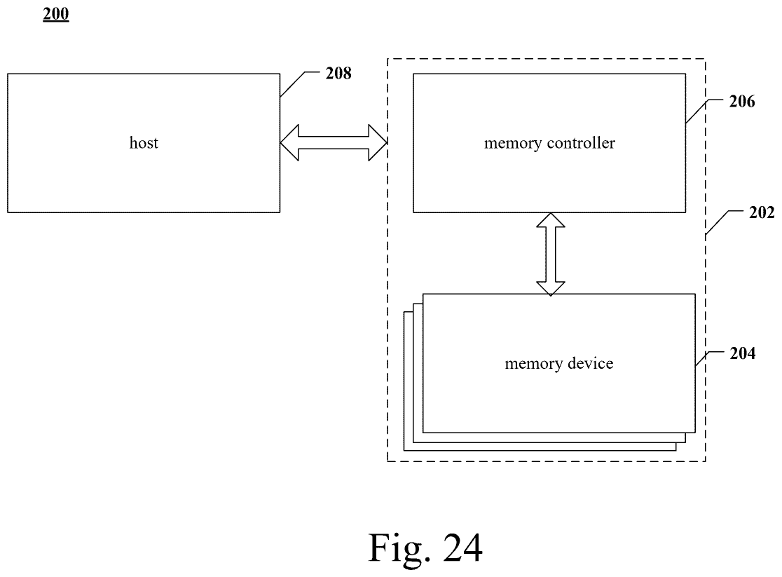

The semiconductor device of examples of the present disclosure may be shown in FIGS. 3 to 7, 20, 22 and 23, the semiconductor device may be a DRAM or at least a part of devices in a DRAM. Alternatively, with reference to FIG. 24, an example of the present disclosure provides a memory system 202 including a memory device 204 including the above-described semiconductor device; and a memory controller 206 coupled with and controlling the memory device 204.

With reference to FIG. 24, an example of the present disclosure provides a system 200 including a host 208. The system 200 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having memories therein. As shown in FIG. 24, system 200 may include a host 208 and a memory system 202 having one or more memory devices 204 and a memory controller 206. The host 208 can be a processor of an electronic device, such as a central processing unit (CPU), or a system-on-chip (SoC), such as an application processor (AP). The host 208 may be configured to send data to the memory device 204 or receive data from the memory device 204.

According to some implementations, the memory controller 206 is coupled to the memory device 204 and the host 208 and is configured to control the memory device 204 for performing read, write or refresh operation. The memory controller 206 can manage the data stored in the memory device 204 and communicate with the host 208. The memory device 204 includes a DRAM or a package structure formed by stacking a plurality of DRAMs such as HBM or HMC package structure. The memory system 202 may serve as the memory in host 208 in the system 200 or a buffer in the system 200. In some specific examples, the memory system 202 may be used to assist solid state disks so as to improve read/write of the solid state disks. At present, most high end solid state disk products use embedded DRAMs to improve product performance and random read/write speed. In an example, while write a file especially a small file, the small file is processed by DRAM and then stored in a flash such that the storage efficiency of the solid state disk is higher and the speed is faster. The flash includes a non-volatile memory including, but not limited to 2D NAND memory or 3D NAND memory.

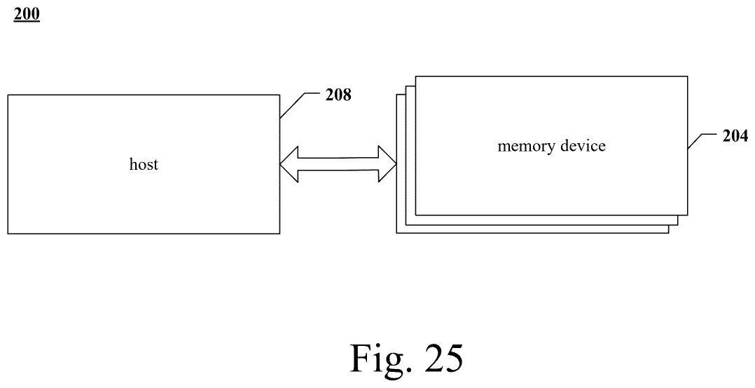

In some other examples, with reference to FIG. 25, the system 200 may only include a host 208 and a memory device 204 coupled therewith. The controller for controlling the memory device 204 may be located in the host 208, for example, the memory controller integrated in the central processing unit (CPU) or the south or north bridge chip integrated in the main board of the system 200. The memory device 204 may include, but not limited to a double-data-rate synchronous dynamic random access memory adopting DDR4 memory specification and DDR5 memory specification, and low-power consumption double-data-rate synchronous dynamic random access memory adopting LPDDR5 memory specification.

It should be understood that in the examples provided in the present disclosure, the disclosed apparatuses and methods may be implemented in non-objective ways. The above-described apparatus examples are only schematic. For example, the division of units is only a logical function division and there may be other division manners upon practical implementation. For example, a plurality of units or parts may be combined or integrated into another system, or some features may be omitted or not executed. In addition, various constituting parts as shown or discussed may be coupled directly or indirectly. The methods disclosed in the method examples provided in the present disclosure may be combined in any manner without conflicts to obtain new method examples.

What have been described above are only implementations of the present disclosure. However, the scope of the present invention is not limited thereto, and variations or substitutions that easily occur to one skilled in the art in the scope disclosed in the present disclosure should be encompassed in the scope of the present disclosure.

What is claimed is:

1. A semiconductor device, comprising a first semiconductor structure, the first semiconductor structure comprising:
a transistor comprising a semiconductor layer extending at least in a first direction and a gate layer extending in a second direction; the semiconductor layer having a first end and a second end disposed oppositely in the first direction with an intermediate region between the first end and the second end;
wherein the semiconductor layer comprises a first semiconductor layer and a second semiconductor layer disposed adjacently in a third direction, and the gate layer comprises a first gate layer and a second gate layer disposed adjacently in the third direction; the first gate layer and the second gate layer being located between the first semiconductor layer and the second semiconductor layer; the third direction intersecting the second direction, and a plane constituted by the third direction and the second direction intersecting the first direction;
wherein the first end of the first semiconductor layer has a first distance from the first end of the second semiconductor layer in the third direction, the intermediate region of the first semiconductor layer has a second distance from the intermediate region of the second semiconductor layer in the third direction; and the first distance is greater than the second distance.

2. The semiconductor device of claim 1, wherein the first semiconductor structure further comprises:
a wall structure extending in the second direction; wherein the semiconductor layer is located on two sides of the wall structure disposed oppositely in the third direction.

3. The semiconductor device of claim 2, wherein the first semiconductor structure further comprises:
a first dielectric layer located between the wall structure and the semiconductor layer;
wherein the wall structure comprises:
a second dielectric layer, a conductive layer, and a third dielectric layer, wherein the second dielectric layer, the conductive layer, and the third dielectric layer are stacked in the first direction, the second dielectric layer being located on a side of the conductive layer close to the first end in the first direction; wherein a size of the second dielectric layer in the third direction is smaller than a size of the conductive layer in the third direction.

4. The semiconductor device of claim 3, wherein the second end of the first semiconductor layer has a third distance from the second end of the second semiconductor layer in the third direction, and the third distance is greater than the second distance.

5. The semiconductor device of claim 4, wherein a size of the third dielectric layer in the third direction is smaller than a size of the conductive layer in the third direction.

6. The semiconductor device of claim 2, wherein the semiconductor layer surrounds the two sides of the wall structure disposed oppositely in the third direction and surrounds one side of the wall structure in the first direction; the semiconductor layer comprises two first ends exposing another side of the wall structure in the first direction; and the semiconductor layer provides channels for two transistors adjacent in the third direction.

7. The semiconductor device of claim 6, wherein the first end comprises a protrusion extending in a direction away from the wall structure.

8. The semiconductor device of claim 1, wherein a constituting material for the semiconductor layer comprises indium gallium zinc oxide (IGZO).

9. The semiconductor device of claim 1, wherein the first semiconductor structure further comprises:
a capacitive structure located on a side of the semiconductor layer close to the first end and coupled with the first end;
a bit line located on a side of the semiconductor layer close to the second end and coupled with the second end, and
a second semiconductor structure located on a side of the bit line away from the semiconductor layer, wherein the second semiconductor structure comprises a peripheral circuit, and the second semiconductor structure is bonded with the first semiconductor structure.

10. The semiconductor device of claim 9, wherein the capacitive structure comprises:
a first electrode, a fourth dielectric layer, and a second electrode, the fourth dielectric layer being located between the first electrode and the second electrode; wherein the first electrode is coupled with the first end, and a plurality of capacitive structures are coupled via the second electrodes.

11. A semiconductor device, comprising:
a semiconductor layer extending at least in a first direction; the semiconductor layer having a first end and a second end disposed oppositely in the first direction;
a wall structure extending in a second direction; the semiconductor layer being located on two sides of the wall structure disposed oppositely in a third direction; the third direction intersecting the second direction, and a plane constituted by the third direction and the second direction intersecting the first direction; and
a first dielectric layer located between the wall structure and the semiconductor layer;
wherein the wall structure comprises a second dielectric layer, a conductive layer, and a third dielectric layer, wherein the second dielectric layer, the conductive layer, and the third dielectric layer are stacked in the first direction, the second dielectric layer being located on a side of the conductive layer close to the first end in the first direction; a size of the second dielectric layer in the third direction is smaller than a size of the conductive layer in the third direction.

12. The semiconductor device of claim 11, wherein a size of the third dielectric layer in the third direction is smaller than a size of the conductive layer in the third direction.

13. The semiconductor device of claim 11, wherein the semiconductor layer surrounds the two sides of the wall structure disposed oppositely in the third direction and surrounds one side of the wall structure in the first direction; the semiconductor layer comprises two first ends exposing another side of the wall structure in the first direction.

14. The semiconductor device of claim 13, wherein the first end comprises a protrusion extending in a direction away from the wall structure.

15. The semiconductor device of claim 11, wherein the semiconductor device further comprises a capacitive structure located on a side of the semiconductor layer close to the first end and coupled with the first end;
a bit line located on a side of the semiconductor layer close to the second end and coupled with the second end; and wherein the wall structure, the semiconductor layer and the bit line are located in a first semiconductor layer, and the semiconductor device further comprises:
a second semiconductor structure located on a side of the bit line away from the semiconductor layer; the second semiconductor structure comprising a peripheral circuit, and the second semiconductor structure being bonded with the semiconductor device.

16. The semiconductor device of claim 15, wherein the capacitive structure comprises:
a first electrode, a fourth dielectric layer and a second electrode, the fourth dielectric layer being located between the first electrode and the second electrode; wherein the first electrode is coupled with the first end; and a plurality of capacitive structures are coupled via the second electrodes.

17. A fabrication method of a semiconductor device, comprising forming a first semiconductor structure, wherein forming the first semiconductor structure comprising:
forming a first dielectric material layer, a first conductive material layer and a second dielectric material layer, wherein the first dielectric material layer, the first conductive material layer, and the second dielectric material layer are stacked in a first direction;
forming a first trench extending through the second dielectric material layer, the first conductive material layers and at least a part of thickness of the first dielectric material layer, the first trench extending in a second direction;
removing a part of first dielectric material layer on bottom of the first trench to form a first opening having an opening direction toward a third direction, to form a wall structure; wherein a size of the remaining first dielectric material layer in the third direction is smaller than a size of the first conductive material layers in the third direction; the third direction intersects the second direction, and a plane constituted by the third direction and the second direction intersects the first direction; and
forming a first dielectric layer and a semiconductor layer on two sides of the wall structure in the third direction with the first dielectric layer located between the wall structure and the semiconductor layer; wherein the semiconductor layer has a first end and a second end disposed oppositely in the third direction, a part of the first dielectric layer is located on inner wall of the first opening, and a part of the first end is located on the inner wall of the first opening.

18. The fabrication method of claim 17, wherein the method of forming the wall structure further comprises:
removing a part of second dielectric material layer at the opening side of the first trench to form a second opening having an opening direction toward the third direction; wherein a size of the remaining second dielectric material layer in the third direction is smaller than a size of the first conductive material layers in the third direction; a part of the first dielectric layer is located on inner wall of the second opening and a part of the second end is located on inner wall of the second opening.

19. The fabrication method of claim 17, wherein the method of forming the semiconductor layer comprises:
forming a first dielectric layer on two sides of the first trench in the third direction;
forming a semiconductor material layer covering the first dielectric layer in the third direction and covering bottom of the first trench in the first direction; and
penetrating through the semiconductor material layer on the bottom of the first trench in the first direction to form the semiconductor layer, with the first end being located on the bottom of the first trench.

20. The fabrication method of claim 17, wherein the method of forming the first semiconductor structure further comprises:
forming a capacitive structure on a side of the semiconductor layer close to the first end, an electrode of the capacitive structure close to the first end being coupled with the first end;
forming a bit line on a side of the semiconductor layer close to the second end, the bit line being coupled with the second end; and
bonding a second semiconductor structure on a side of the bit line away from the semiconductor layer, the second semiconductor structure comprising a peripheral circuit.
